(19) United States
(12) Patent Application Publication
(10) Pub. No.: US 2007/0205428 A1
(43) Pub. Date: Sep. 6, 2007

(54) LIGHT-EMITTING MATERIAL, LIGHT-EMITTING ELEMENT, LIGHT-EMITTING DEVICE, ELECTRONIC DEVICE, AND MANUFACTURING METHOD OF LIGHT-EMITTING MATERIAL

(75) Inventors: Miki KATAYAMA, Atsugi (JP); Kohei YOKOYAMA, Ayase (JP); Junichiro SAKATA, Atsugi (JP)

Correspondence Address: FISH & RICHARDSON P.C., P.O. BOX 1022, MINNEAPOLIS, MN, 55440-1022, US

(73) Assignee: SEMICONDUCTOR ENERGY LABORATORY CO., LTD., Atsugi-shi (JP)

(21) Appl. No.: 11/679,360

(22) Filed: Feb. 27, 2007

(30) Foreign Application Priority Data
Mar. 3, 2006 (JP) 2006-058757

(51) Int. Cl. H01L 33/00

(52) U.S. Cl. 257/103

(57) ABSTRACT

To provide a light-emitting material made of an inorganic compound, which exhibits higher luminance than the conventional material, due to its crystal structure. The light-emitting material includes a host material and an impurity element which serves as a luminescence center. The main crystal structure of the light-emitting material is hexagonal. The host material is a compound of a Group 2 element and a Group 16 element, or a compound of a Group 12 element and a Group 16 element. The impurity element includes at least one of manganese (Mn), samarium (Sm), terbium (Tb), erbium (Er), thulium (Tm), europium (Eu), cerium (Ce), and praseodymium (Pr).

### TECHNICAL FIELD

The present invention relates to a light-emitting material of a light-emitting element which utilizes electroluminescence. In addition, the invention relates to a light-emitting element which utilizes electroluminescence, and also relates to a light-emitting device and an electronic device having such a light-emitting emitting element.

### BACKGROUND ART

In recent years, research and development of a light-emitting element which utilizes electroluminescence have been actively conducted. The basic structure of a light-emitting element is such that a light-emissive substance is interposed between a pair of electrodes, and light emission can be obtained from the light-emissive substance by applying a voltage to the opposite electrodes.

Being a self-luminous type, such a light-emitting element has advantages over liquid crystal displays in that it has wide viewing angles, high visibility, and high response speed as well as the feasibility of reduction in thickness and weight.

A light-emitting element can be categorized as an organic light-emitting element which uses an organic compound as a light-emissive substance or an inorganic light-emitting element which uses an inorganic compound as a light-emissive substance.

These light-emitting elements differ not only in the light-emissive substance but also in the light-emission mechanism and individual characteristics.

Between the two, the inorganic light-emitting element has, as shown in FIG. 10, a double-insulator structure in which a light-emitting layer 1503 is interposed between insulating films (a first insulating film 1502 and a second insulating film 1504) which are interposed between a pair of electrodes (a first electrode 1501 and a second electrode 1505). When an AC (Alternating-Current) voltage is applied to the opposite electrodes (the first electrode 1501 and the second electrode 1505) from respective power supplies (a first power supply 1506 and a second power supply 1507), light emission can be obtained.

In addition, the inorganic light-emitting element is categorized as a dispersed light-emitting element or a thin-film light-emitting element according to the element structure. The former dispersed light-emitting element has a light-emitting layer in which a particulate light-emitting material is dispersed in a binder, while the latter thin-film light-emitting element has a light-emitting layer made of a thin film of a light-emitting material. Although the two light-emitting elements are different in the above points, they have a common characteristic in that both require electrons that are accelerated by a high electric field. As types of a light-emission mechanism, there are donor-acceptor-recombination luminescence which utilizes the donor level and the acceptor level, and local luminescence which utilizes inner-shell electron transition of metal ions.

Although the inorganic light-emitting element is superior to the organic light-emitting element in terms of the reliability of materials, sufficient luminance and the like have not been obtained so far, and various researches have been conducted to attain the sufficient level (for example, see Reference 1: Japanese Published Patent Application No. 2001-250691).

An inorganic light-emitting element has a light-emission mechanism that light emission is obtained by collision excitation of electrons, which have been accelerated by a high electric field, against the luminescence center material; therefore, a voltage of several hundred V is required to be applied to the light-emitting element. However, in order to apply a light-emitting element to a display panel or the like, it is necessary to use a light-emitting element with a low driving voltage and high luminance.

### DISCLOSURE OF INVENTION

It is an object of the invention to provide a light-emitting material formed using an inorganic compound, which exhibits higher luminance than the conventional material, due to its crystal structure. It is another object of the invention to provide a light-emitting element capable of low-voltage driving. It is still another object of the invention to provide a light-emitting device and an electronic device with reduced power consumption. It is yet another object of the invention to provide a light-emitting device and an electronic device which can be manufactured at low cost.

It is a feature of the invention to provide a light-emitting material with high luminous efficiency, by forming the main crystal structure to be hexagonal. It is another feature of the invention to form a light-emitting element, a light-emitting device, or an electronic device which has high luminance, by using the light-emitting material.

A light-emitting material of the invention includes a host material and an impurity element which serves as a luminescence center. The main crystal structure of the light-emitting material is hexagonal. The host material is a compound of a Group 2 element and a Group 16 element, or a compound of a Group 12 element and a Group 16 element, while the impurity element includes at least one of manganese (Mn), samarium (Sm), terbium (Tb), erbium (Er), thulium (Tm), europium (Eu), cerium (Ce), and praseodymium (Pr).

Another light-emitting material of the invention includes a host material, an impurity element which serves as a luminescence center, and a Group 14 element. The main crystal structure of the light-emitting material is hexagonal. The host material is a compound of a Group 2 element and a Group 16 element, or a compound of a Group 12 element and a Group 16 element, while the impurity element includes at least one of manganese (Mn), samarium (Sm), terbium (Tb), erbium (Er), thulium (Tm), europium (Eu), cerium (Ce), and praseodymium (Pr).

In the light-emitting material of the invention, the Group 14 element is carbon (C), silicon (Si), germanium (Ge), tin (Sn), or lead (Pb).

In the light-emitting material of the invention, the compound of the Group 2 element and the Group 16 element includes magnesium oxide (MgO), calcium oxide (CaO), strontium oxide (SrO), barium oxide (BaO), magnesium sulfide (MgS), calcium sulfide (CaS), strontium sulfide (SrS), barium sulfide (BaS), magnesium selenide (MgSe), calcium selenide (CaSe), strontium selenide (SrSe), barium selenide (BaSe), magnesium telluride (MgTe), calcium telluride (CaTe), strontium telluride (SrTe), or barium telluride (BaTe).

In the light-emitting material of the invention, the compound of the Group 12 element and the Group 16 element includes zinc oxide (ZnO), cadmium oxide (CdO), mercury oxide (HgO), zinc sulfide (ZnS), cadmium sulfide (CdS), mercury sulfide (HgS), zinc selenide (ZnSe), cadmium selenide (CdSe), mercury selenide (HgSe), zinc telluride (ZnTe), cadmium telluride (CdTe), or mercury telluride (HgTe).

A light-emitting element of the invention includes a first electrode, a second electrode, and a light-emitting layer interposed between the first electrode and the second electrode. The light-emitting layer includes a light-emitting material containing a host material and an impurity element which serves as a luminescence center. The main crystal structure of the light-emitting material is hexagonal. The host material is a compound of a Group 2 element and a Group 16 element, or a compound of a Group 12 element and a Group 16 element, while the impurity element includes at least one of manganese (Mn), samarium (Sm), terbium (Tb), erbium (Er), thulium (Tm), europium (Eu), cerium (Ce), and praseodymium (Pr).

A light-emitting element of the invention includes a first electrode, a second electrode, and a tight-emitting layer interposed between the first electrode and the second electrode. The light-emitting layer includes a light-emitting material containing a host material, an impurity element which serves as a luminescence center, and a Group 14 element. The main crystal structure of the light-emitting material is hexagonal. The host material is a compound of a Group 2 element and a Group 16 element, or a compound of a Group 12 element and a Group 16 element, while the impurity element includes at least one of manganese (Mn), samarium (Sm), terbium (Tb), erbium (Er), thulium (Tm), europium (Eu), cerium (Ce), and praseodymium (Pr).

In the light-emitting element of the invention, the Group 14 element is carbon (C), silicon (Si), germanium (Ge), tin (Sn), or lead (Pb).

In the light-emitting element of the invention, the compound of the Group 2 element and the Group 16 element includes magnesium oxide (MgO), calcium oxide (CaO), strontium oxide (SrO), barium oxide (BaO), magnesium sulfide (MgS), calcium sulfide (CaS), strontium sulfide (SrS), barium sulfide (BaS), magnesium selenide (MgSe), calcium selenide (CaSe), strontium selenide (SrSe), barium selenide (BaSe), magnesium telluride (MgTe), calcium telluride (CaTe), strontium telluride (SrTe), or barium telluride (BaTe).

In the light-emitting element of the invention, the compound of the Group 12 element and the Group 16 element includes zinc oxide (ZnO), cadmium oxide (CdO), mercury oxide (HgO), zinc sulfide (ZnS), cadmium sulfide (CdS), mercury sulfide (HgS), zinc selenide (ZnSe), cadmium selenide (CdSe), mercury selenide (HgSe), zinc telluride (ZnTe), cadmium telluride (CdTe), or mercury telluride (HgTe).

A light-emitting device or an electronic device of the invention includes the above-described light-emitting element.

A manufacturing method of a light-emitting material of the invention includes the step of baking a host material and an impurity element which serves as a luminescence center, thereby forming the main crystal structure into a hexagonal crystal structure. The host material is a compound of a Group 2 element and a Group 16 element, or a compound of a Group 12 element and a Group 16 element, while the impurity element includes at least one of manganese (Mn), samarium (Sm), terbium (Tb), erbium (Er), thulium (Tm), europium (Eu), cerium (Ce), and praseodymium (Pr).

A manufacturing method of a light-emitting material of the invention includes the step of baking a host material, an impurity element which serves as a luminescence center, and a Group 14 element, thereby forming the main crystal structure into a hexagonal crystal structure. The host material is a compound of a Group 2 element and a Group 16 element, or a compound of a Group 12 element and a Group 16 element, while the impurity element includes at least one of manganese (Mn), samarium (Sm), terbium (Tb), erbium (Er), thulium (Tm), europium (Eu), cerium (Ce), and praseodymium (Pr).

In the manufacturing method of a light-emitting material of the invention, the Group 14 element is carbon (C), silicon (Si), germanium (Ge), tin (Sn), or lead (Pb).

In the manufacturing method of a light-emitting material of the invention, the compound of the Group 2 element and the Group 16 element includes magnesium oxide (MgO), calcium oxide (CaO), strontium oxide (SrO), barium oxide (BaO), magnesium sulfide (MgS), calcium sulfide (CaS), strontium sulfide (SrS), barium sulfide (BaS), magnesium selenide (MgSe), calcium selenide (CaSe), strontium selenide (SrSe), barium selenide (BaSe), magnesium telluride (MgTe), calcium telluride (CaTe), strontium telluride (SrTe), or barium telluride (BaTe).

In the manufacturing method of a light-emitting material of the invention, the compound of the Group 12 element and the Group 16 element includes zinc oxide (ZnO), cadmium oxide (CdO), mercury oxide (HgO), zinc sulfide (ZnS), cadmium sulfide (CdS), mercury sulfide (HgS), zinc selenide (ZnSe), cadmium selenide (CdSe), mercury selenide (HgSe), zinc telluride (ZnTe), cadmium telluride (CdTe), or mercury telluride (HgTe).

In the invention, by forming a light-emitting material whose main crystal structure is hexagonal, using a host material and an impurity element which serves as a luminescence center, luminance higher than that of the conventional material can be obtained. In addition, since a light-emitting element of the invention includes the light-emitting material whose main crystal structure is hexagonal, a light-emitting element with high luminous efficiency, low driving voltage, and high resistance to deterioration can be provided. Furthermore, since a light-emitting device of the invention includes the light-emitting element including a light-emitting material whose main crystal structure is hexagonal, power consumption can be reduced. In addition, since a driver circuit with high withstand voltage is not required, the manufacturing cost of the light-emitting device can be reduced.

### BRIEF DESCRIPTION OF DRAWINGS

In the accompanying drawings:

FIG. 1 illustrates a light-emitting element of the invention;

FIGS. 2A to 2C illustrate light-emitting elements of the invention;

FIG. 3 illustrates a light-emitting device of the invention;

FIGS. 4A and 4B illustrate a light-emitting device of the invention;

FIGS. 5A to 5D illustrate electronic devices of the invention;

FIG. 6 illustrates an electronic device of the invention;

FIG. 7 shows the result of XRD analysis of ZnS:Mn;

FIG. 8 shows the result of XRD analysis of ZnS:MnS;

FIG. 9 shows the result of XRD analysis of ZnS:MnS:Si; and

FIG. 10 illustrates a conventional light-emitting element.

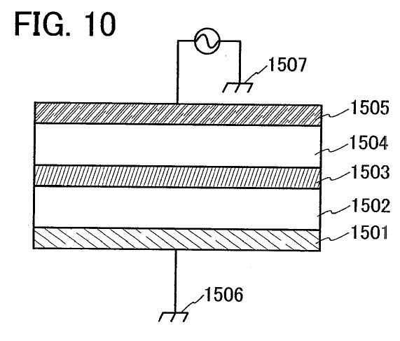

### BEST MODE FOR CARRYING OUT THE INVENTION

Embodiment modes of the invention will be described in detail below with reference to the accompanying drawings. Note that it will be easily understood by those skilled in the art that the invention can be implemented in various different ways. Thus, various changes and modifications can be made without departing from the spirit and scope of the invention. Therefore, the invention should not be construed as being limited to the description in the following embodiment modes.

### Embodiment Mode 1

This embodiment mode will describe a light-emitting material for forming a light-emitting element with high luminance. Note that the light-emitting material in this embodiment mode includes a host material and an impurity element which serves as a luminescence center, and the main crystal structure of the light-emitting material is hexagonal.

The luminous efficiency of an inorganic light-emitting element is determined by the crystal structure of an inorganic material such as sulfide which is the host material and an impurity element which serves as the luminescence center, in a light-emitting layer. When the main crystal structure of a light-emitting material is formed to be hexagonal, PL (photoluminescence) whose luminance is higher than that of the conventional material can be obtained, and thus the luminous efficiency can be improved. In this embodiment mode, a light-emitting material having many hexagonal crystal structures is described as an exemplary light-emitting material of a light-emitting element with high luminance.

A light-emitting material whose main crystal structure is hexagonal can be formed by baking a host material and an impurity element serving as a luminescence center at 700 to 1500° C. For example, in the case of using zinc sulfide (ZnS) as the host material and manganese (Mn) as the impurity element, Zn of ZnS which is the host material is partially substituted by Mn which is the luminescence center, so that a cubic or hexagonal crystal structure is obtained. After that, by reacting the material by heating at 700 to 1500° C. in an electric furnace, the material can be changed into a material whose main crystal structure is hexagonal.

Alternatively, as a light-emitting material whose main crystal structure is hexagonal, a Group 14 element of the periodic table may further be added into the host material and the impurity element serving as a luminescence center. By adding the Group 14 element into the host material and the impurity element serving as a luminescence center, reaction can be induced by which a cubic crystal structure included in the light-emitting material is changed into a hexagonal crystal structure. Therefore, a material having a hexagonal crystal structure can be formed more efficiently.

In this embodiment mode, carbon (C), silicon (Si), germanium (Ge), tin (Sn), lead (Pb), or the like can be used as the Group 14 element, for example. However, the material to be added into the host material and the impurity element is not limited to the Group 14 element, and it is acceptable as long as a material whose main crystal structure is hexagonal can be obtained.

As the host material, a compound of a Group 2 element and a Group 16 element of the periodic table, or a compound of a Group 12 element and a Group 16 element of the periodic table can be used. However, the invention is not limited to these.

As examples of the compound of the Group 2 element and the Group 16 element, magnesium oxide (MgO), calcium oxide (CaO), strontium oxide (SrO), barium oxide (BaO), magnesium sulfide (MgS), calcium sulfide (CaS), strontium sulfide (SrS), barium sulfide (BaS), magnesium selenide (MgSe), calcium selenide (CaSe), strontium selenide (SrSe), barium selenide (BaSe), magnesium telluride (MgTe), calcium telluride (CaTe), strontium telluride (SrTe), barium telluride (BaTe), and the like can be given. Alternatively, the compound may contain two or more atoms of one or both of the Group 2 element and the Group 16 element.

As examples of the compound of the Group 12 element and the Group 16 element, zinc oxide (ZnO), cadmium oxide (CdO), mercury oxide (HgO), zinc sulfide (ZnS), cadmium sulfide (CdS), mercury sulfide (HgS), zinc selenide (ZnSe), cadmium selenide (CdSe), mercury selenide (HgSe), zinc telluride (ZnTe), cadmium telluride (CdTe), mercury telluride (HgTe), and the like can be given. Alternatively, the compound may contain two or more atoms of one or both of the Group 12 element and the Group 16 element.

The impurity element which serves as the luminescence center contains at least one of manganese (Mn), copper (Cu), samarium (Sm), terbium (Tb), erbium (Er), thulium (Tm), europium (Eu), cerium (Ce), praseodymium (Pr), silver (Ag), lead (Pb), and the like. Alternatively, an inorganic compound containing such an impurity element can be used. By adding the impurity element which can serve as the luminescence center, light emission which utilizes inner-shell electron transition of metal ions can be obtained. Note that the impurity element serving as the luminescence center is not limited to a metal element alone, and a halogen element such as fluorine (F) or chlorine (Cl) may also be added for the purpose of charge compensation. However, the invention is not limited to these. Note that it is preferable to use manganese (Mn), samarium (Sm), terbium (Tb), erbium (Er), thulium (Tm), europium (Eu), cerium (Ce), or praseodymium (Pr) as the impurity element serving as the luminescence center, with which a light-emitting material whose main crystal structure is hexagonal and whose luminous efficiency is higher can be formed.

By baking the host material and the impurity element serving as the luminescence center at 700 to 1500° C., a light-emitting material whose main crystal structure is hexagonal and whose luminance is sufficiently high can be obtained. Alternatively, by further adding the Group 14 element into the host material and the impurity element serving as the luminescence center, and baking them at 700 to 1500° C., a light-emitting material whose main crystal structure is hexagonal can be efficiently formed, and thus a light-emitting material with high luminance can be obtained.

In the case of using ZnS as the host material, a light-emitting material whose main crystal structure is hexagonal can be efficiently formed by mixing each material at a ratio of, for example, ZnS (100 mol %), Mn or MnS (1 to 10 mol %), and Si (1 to 10 mol %).

By using the light-emitting material shown in this embodiment mode for a light-emitting layer of a light-emitting element, a light-emitting element with high luminance can be obtained.

### Embodiment Mode 2

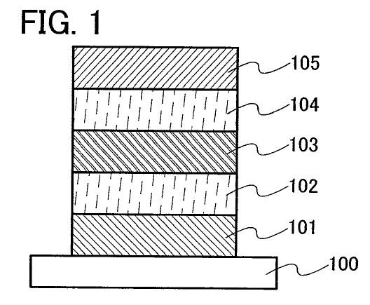

This embodiment mode will describe a light-emitting element formed using the material shown in Embodiment Mode 1, with reference to FIG. 1. Note that in this embodiment mode, a thin-film light-emitting element is described.

The light-emitting element shown in this embodiment mode has a structure where, as shown in FIG. 1, a first electrode 101 and a second electrode 105 are provided over a substrate 100, a light-emitting layer 103 is provided between the first electrode 101 and the second electrode 105, a first dielectric layer 102 is provided between the first electrode 101 and the light-emitting layer 103, and a second dielectric layer 104 is provided between the light-emitting layer 103 and the second electrode 105. Note that the structure of the light-emitting element is not limited to the one shown in FIG. 1, and a structure having only one of the first dielectric layer 102 and the second dielectric layer 104 may be employed. Note also that in this embodiment mode, description will be made below on the assumption that the first electrode 101 functions as an anode and the second electrode 105 functions as a cathode.

The substrate 100 is used as a support of the light-emitting element. As the substrate 100, glass, quartz, plastic, or the like can be used, for example. Note that any other materials can be used as long as they can function as the support in the manufacturing process of the light-emitting element.

As a material of the first electrode 101 and the second electrode 105, a metal, an alloy, a conductive compound, or a mixture of them can be used. Specifically, conductive metal oxide such as indium tin oxide (ITO), ITO containing silicon or silicon oxide, indium zinc oxide (IZO), indium oxide containing tungsten oxide and zinc oxide (IWZO), and the like can be given as examples.

A film of such conductive metal oxide is generally deposited by sputtering. For example, the film of indium zinc oxide (IZO) can be formed by sputtering using a target in which zinc oxide of 1 to 20 wt % is added into indium oxide. In addition, the film of indium oxide containing tungsten oxide and zinc oxide (IWZO) can be formed by sputtering using a target in which tungsten oxide of 0.5 to 5 wt % and zinc oxide of 0.1 to 1 wt % are added into indium oxide. Alternatively, the first electrode 101 and the second electrode 105 can be formed using a material such as aluminum (Al), silver (Ag), gold (Au), platinum (Pt), nickel (Ni), tungsten (W), chromium (Cr), molybdenum (Mo), iron (Fe), cobalt (Co), copper (Cu), palladium (Pd), or nitride of a metal material (e.g., titanium nitride: TiN).

Note that in the case of forming the first electrode 101 or the second electrode 105 as a light-transmitting electrode, the light-transmitting electrode can be formed by depositing even a material with low transmittance of visible light, to have a thickness of 1 to 50 nm, or preferably 5 to 20 nm. Not only sputtering, but also vacuum deposition, CVD, or a sol-gel method can be used to form the electrodes.

Note also that since light emission is extracted to outside through the first electrode 101 or the second electrode 105, at least one of the first electrode 101 and the second electrode 105 should be formed of a light-transmitting material. In addition, it is preferable to select materials so that the first electrode 101 has a higher work function than the second electrode 105.

As a material for forming the light-emitting layer 103, a light-emitting material whose main crystal structure is hexagonal, which is shown in Embodiment Mode 1, can be used.

As a material for forming the first and second dielectric layers 102 and 104, inorganic materials such as oxide are used. For example, barium titanate (BaTiO₃), tantalum pentoxide (Ta₂O₅), or the like which has a high dielectric constant can be used.

When using a material in which an impurity element is added into a host material, as the light-emitting material in accordance with the invention, a solid-phase reaction is conducted, i.e., sulfide which is the host material and the impurity element are weighed and mixed in a mortar, and then the mixture is reacted by heating in an electric furnace, so that the sulfide can contain the impurity element. The baking temperature is preferably 700 to 1500° C. This is because the solid-phase reaction will not proceed at a temperature much lower than 700° C., whereas sulfide will be decomposed at a temperature much higher than 1500° C. Note that the baking may be conduced with a powder state, but is preferably conducted with a pellet state.

As the impurity element used for the light-emitting material in accordance with the invention, which is formed by using a solid-phase reaction, it is also possible to use a compound containing an impurity element which serves as a luminescence center. In that case, the impurity element can be easily diffused and the solid-phase reaction can smoothly advance; therefore, a light-emitting material with a uniform luminescence center can be obtained. Furthermore, since an excessive amount of the impurity element will not be mixed in the light-emitting material, a high-purity light-emitting material can be obtained. As a compound containing an impurity element serving as the luminescence center, it is possible to use, for example, copper fluoride (CuF₂), copper chloride (CuCl), copper iodide (CuI), copper bromide (CuBr), copper nitride (Cu₃N), copper phosphide (Cu₃P), silver fluoride (AgF), silver chloride (AgCl), silver iodide (AgI), silver bromide (AgBr), gold chloride (AuCl₃), gold bromide (AuBr₃), and the like.

As a method for forming the light-emitting layer 103, the first dielectric layer 102, and the second dielectric layer 104, the following can be used: a vacuum evaporation method such as resistance-heating evaporation or electron-beam evaporation (EB evaporation), a physical vapor deposition (PVD) method such as sputtering, a chemical vapor deposition (CVD) method such as metal organic CVD or low-pressure hydride transport CVD, an atomic layer epitaxy (ALE) method, or the like. Alternatively, an ink-jet deposition method, a spin coating method, or the like can also be used. The thickness of the light-emitting layer 103, the first dielectric layer 102, and the second dielectric layer 104 is not specifically limited, but is preferably in the range of 10 to 1000 nm.

By the invention, a light-emitting element which can operate with either a DC voltage or an AC voltage, and is capable of low-voltage driving can be provided. Furthermore, since the light-emitting element can emit light with a low driving voltage, a light-emitting element with reduced power consumption can be provided.

In this embodiment mode, a light-emitting material having a hexagonal crystal structure is used for the light-emitting layer; therefore, a light-emitting element with high luminance can be obtained.

### Embodiment Mode 3

This embodiment mode will describe a structure of a dispersed light-emitting element formed using the material shown in Embodiment Mode 1.

In the case of a dispersed light-emitting element, a film-form light-emitting layer is formed by dispersing a particulate light-emitting material into a binder. When particles with a desired size cannot be sufficiently obtained depending on manufacturing methods of light-emitting materials, the material may be processed into fine particles by grinding with a mortar or the like. A binder is a substance for fixing a particulate light-emitting material in a dispersed state, and holding the shape of the material as a light-emitting layer. With the binder, the light-emitting material is uniformly dispersed and fixed in the light-emitting layer.

In the case of a dispersed light-emitting element, a light-emitting layer can be formed by a droplet discharge method by which a light-emitting layer can be selectively formed, a printing method (e.g., screen printing or offset printing), a coating method such as spin coating, a dipping method, a dispenser method, or the like. Although the thickness of the light-emitting layer is not specifically limited, it is preferably in the range of 10 to 1000 nm. In the light-emitting layer containing a light-emitting material and a binder, the percentage of the light-emitting material is preferably in the range of 50 to 80 wt %.

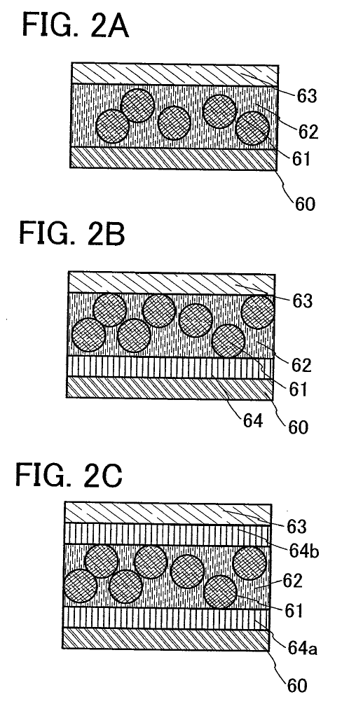

FIGS. 2A to 2C show examples of a dispersed light-emitting element which can be used as the light-emitting element of the invention. A light-emitting element shown in FIG. 2A has a stacked structure of a first electrode 60, a light-emitting layer 62, and a second electrode 63. The light-emitting layer 62 contains a light-emitting material 61 which is held with a binder. Note that in this embodiment mode, a material similar to the one shown in Embodiment Mode 1 can be used as the light-emitting material 61.

As a binder which can be used for the dispersed light-emitting element in this embodiment mode, an organic material, an inorganic material, or a mixed material of an organic material and an inorganic material can be used. As an organic material, polymers with a relatively high dielectric constant such as a cyanoethyl cellulose resin can be used as well as a polyethylene resin, a polypropylene resin, a polystyrene resin, a silicone resin, an epoxy resin, a vinylidene fluoride resin, or the like. Alternatively, thermally stable polymers such as aromatic polyamide or polybenzimidazole, or a siloxane resin can be used. The siloxane resin is a resin having a skeletal structure with the bond of silicon (Si) and oxygen (O) (Si—O—Si bond). As a substituent of siloxane, an organic group containing at least hydrogen (e.g., an alkyl group or aromatic hydrocarbon) is used. Alternatively, a fluoro group may be used as a substituent, or both a fluoro group and an organic group containing at least hydrogen can be used as a substituent. It is also possible to use, as an organic material, a vinyl resin such as polyvinyl alcohol or polyvinyl butyral; a phenol resin; a novolac resin; an acrylic resin; a melamine resin; or a urethane resin. In addition, an oxazole resin such as a photo-curing polybenzoxazole resin can be used. When such a resin is mixed with fine particles with a high dielectric constant such as barium titanate (BaTiO₃) or strontium titanate (SrTiO₃) as appropriate, the dielectric constant can be controlled.

As an inorganic material contained in the binder, the following materials can be used: silicon oxide (SiOₓ); silicon nitride (SiNₓ); silicon containing oxygen and nitrogen; aluminum nitride (AlN); aluminum containing oxygen and nitrogen, or aluminum oxide (Al₂O₃); titanium oxide (TiO₂); BaTiO₃; SrTiO₃; lead titanate (PbTiO₃); potassium niobate (KNbO₃); lead niobate (PbNbO₃); tantalum oxide (Ta₂O₅); barium tantalate (BaTa₂O₆); lithium tantalate (LiTaO₃); yttrium oxide (Y₂O₃); zirconium oxide (ZrO₂); ZnS; or a substance containing other inorganic materials. When an inorganic material with a high dielectric constant is added into the organic material, it becomes easier to control the dielectric constant of the light-emitting layer which is made of the light-emitting material and the binder, and thus, the dielectric constant can be further increased.

In the manufacturing process of the dispersed light-emitting element in this embodiment mode, a light-emitting material is dispersed in a solution containing a binder. For a solvent of the solution containing the binder, which can be used in this embodiment mode, it is possible to appropriately select a solvent in which a binder material is dissolved and which can form a solution with a viscosity suitable for the method for forming a light-emitting layer (various wet processes) and for the desired thickness. An organic solvent or the like can be used; for example, in the case of using a siloxane resin as a binder, propylene glycol monomethyl ether, propylene glycol monomethyl ether acetate (also called PGMEA), 3-methoxy-3-methyl-1-butanol (also called MMB), or the like can be used.

The light-emitting elements shown in FIGS. 2B and 2C each have a structure where the light-emitting element in FIG. 2A is provided with a dielectric layer between the electrode and the light-emitting layer. The light-emitting element shown in FIG. 2B has a dielectric layer 64 between the first electrode 60 and the light-emitting layer 62, while the light-emitting element shown in FIG. 2C has a dielectric layer 64a between the first electrode 60 and the light-emitting layer 62, and a dielectric layer 64b between the second electrode 63 and the light-emitting layer 62. In this manner, the dielectric layer may be provided between one of the electrodes and the light-emitting layer, or between each of the electrodes and the light-emitting layer. Furthermore, the dielectric layer may have either a single layer or stacked layers of a plurality of layers.

Although the dielectric layer 64 is provided in contact with the first electrode 60 in FIG. 2B, the stacking order of the dielectric layer and the light-emitting layer may be reversed so that the dielectric layer 64 is in contact with the second electrode 63.

Although the dielectric layer 64 like the one shown in FIG. 2B is not specifically limited, it is preferably a film having a high withstand voltage, dense film quality, and a high dielectric constant. For example, silicon oxide (SiO₂), yttrium oxide (Y₂O₃), titanium oxide (TiO₂), aluminum oxide (Al₂O₃), hafnium oxide (HfO₂), tantalum oxide (Ta₂O₅), barium titanate (BaTiO₃), strontium titanate (SrTiO₃), lead titanate (PbTiO₃), silicon nitride (Si₃N₄), zirconium oxide (ZrO₂), or the like; a mixed film including these; or a stacked film including at least two kinds of the above materials can be used as the dielectric layer. A dielectric layer using such materials can be deposited by sputtering, vapor deposition, CVD, or the like. Alternatively, the dielectric layer may be formed by dispersing particles of the above insulating material into a binder. The binder may be obtained by using a similar material and method to the binder contained in the light-emitting layer. In addition, although the thickness of the dielectric layer is not specifically limited, it is preferably in the range of 10 to 1000 nm.

The light-emitting element shown in this embodiment mode can exhibit light emission when a voltage is applied to the pair of electrodes sandwiching the light-emitting layer. Such a light-emitting element can operate with either a DC voltage or an AC voltage.

In this embodiment mode, a material having a hexagonal crystal structure is used as a light-emitting material; therefore, a light-emitting element with high luminance can be provided.

### Embodiment Mode 4

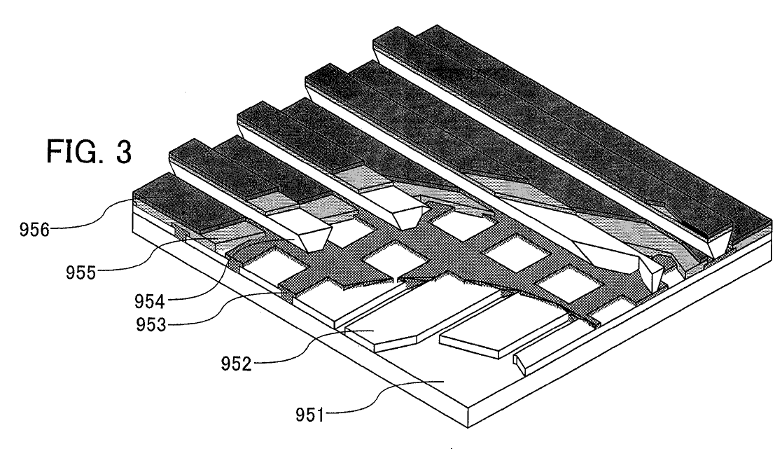

This embodiment mode will describe a light-emitting device having the light-emitting element of the invention, with reference to FIG. 3.

The light-emitting device shown in this embodiment mode is a passive matrix light-emitting device where light-emitting elements are driven without using driving elements such as transistors. FIG. 3 is a perspective view of a passive matrix light-emitting device which is manufactured by using the invention.

In FIG. 3, an electrode 952 and an electrode 956 are provided over a substrate 951, and a layer 955 is provided between the electrode 952 and the electrode 956. Note that the layer 955 includes the light-emitting layer shown in Embodiment Mode 1, which is made of a light-emitting material whose main crystal structure is hexagonal.

Side edges of the electrode 952 are covered with an insulating layer 953. In addition, a partition layer 954 is provided over the insulating layer 953. Side surfaces of the partition layer 954 have tapered slopes with a shape that the distance between the opposite side surfaces is narrower near the substrate surface. That is, a cross section of the partition layer 954 in the short-side direction is trapezoidal, where the bottom base (a base in the same direction as the plane direction of the insulating layer 953, which has a contact with the insulating layer 953) is shorter than the top base (a base in the same direction as the plane direction of the insulating layer 953, which has no contact with the insulating layer 953). Thus, provision of the partition layer 954 can prevent defects of the light-emitting elements which would otherwise be caused by static electricity or the like. Furthermore, by using the light-emitting element of the invention which operates with a low driving voltage, it also becomes possible to drive the passive matrix light-emitting device with low power consumption.

In addition, since the light-emitting device of the invention does not require a driver circuit with high withstand voltage, the manufacturing cost of the light-emitting device can be reduced. Furthermore, reduction in weight of the light-emitting device and reduction in size of a driver circuit portion can be achieved.

In this embodiment mode, a light-emitting material having a hexagonal crystal structure is used for a light-emitting layer; therefore, a light-emitting device with high luminance can be obtained.

### Embodiment Mode 5

This embodiment mode will describe a light-emitting device having the light-emitting element of the invention.

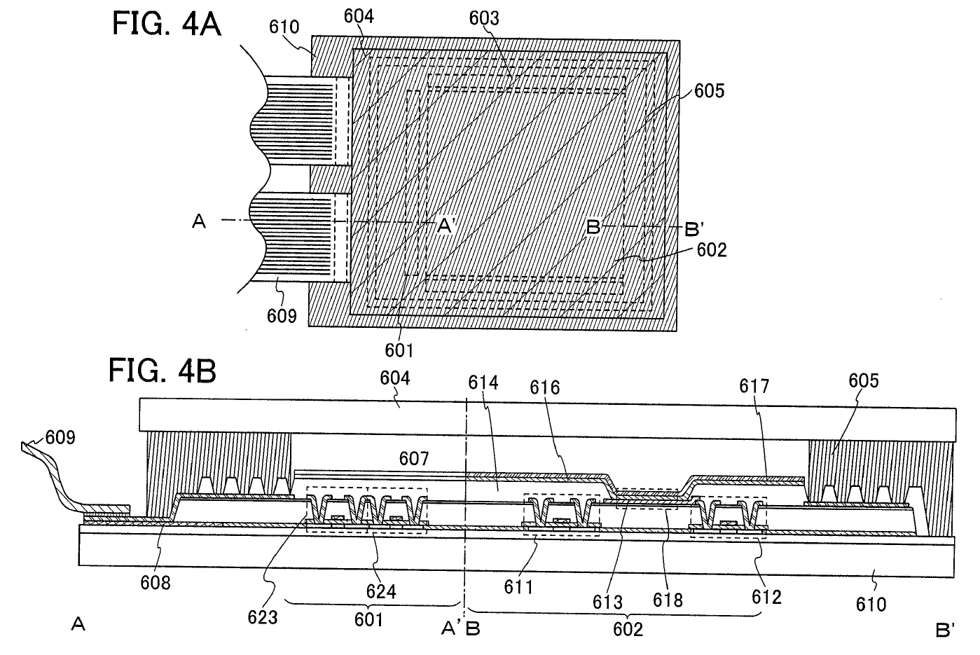

In this embodiment mode, an active matrix light-emitting device in which drive of a light-emitting element is controlled with a transistor is described. Specifically, a light-emitting device whose pixel portion has a light-emitting element of the invention is described, with reference to FIGS. 4A and 4B. Note that FIG. 4A is a top view of a light-emitting device, and FIG. 4B is a cross-sectional view taken along lines A-A′ and B-B′ in FIG. 4A. In portions indicated by dashed lines in FIG. 4A, reference numeral 601 denotes a driver circuit portion (a source driver circuit), 602 denotes a pixel portion, and 603 denotes a driver circuit portion (a gate driver circuit). In addition, reference numeral 604 denotes a sealing substrate, 605 denotes a sealant, and the inner side of the sealant 605 is a space 607.

Note that a lead wire 608 is a wire for transmitting signals to be input to the source driver circuit 601 and the gate driver circuit 603. The lead wire 608 receives video signals, clock signals, start signals, reset signals, and the like from an FPC (Flexible Printed Circuit) 609 which serves as an external input terminal. Although only the FPC is shown here, a printed wiring board (PWB) may be attached to the FPC. The light-emitting device in this specification includes not only the main body of the light-emitting device, but also includes the light-emitting device with an FPC or a PWB attached thereto.

Next, a cross-sectional structure is described with reference to FIG. 4B. Although the driver circuit portions and the pixel portion are actually formed over the element substrate 601, shown herein are only the source driver circuit 601 which is a driver circuit portion, and one pixel included in the pixel portion 602.

Note that a CMOS circuit which combines an n-channel TFT 623 and a p-channel TFT 624 is formed in the source driver circuit 601. Alternatively, TFTs for forming the driver circuit may have any configuration of a known CMOS circuit, PMOS circuit, and NMOS circuit. In addition, although this embodiment mode shows a built-in driver type where the driver circuits are formed over the same substrate as the pixel portion, the invention is not limited to this, and the driver circuits may be formed outside the substrate.

The pixel portion 602 is formed from a plurality of pixels each including a switching TFT 611, a current-controlling TFT 612, and a first electrode 613 electrically connected to a drain of the current-controlling TFT 612. Note that an insulating film 614 is formed to cover the edge of the first electrode 613. Here, the insulating film 614 is formed by using a positive photosensitive acrylic resin film.

In order to obtain an excellent coverage, the insulating film 614 is formed to have a curved surface with a curvature at its top end or bottom end. For example, in the case of using positive photosensitive acrylic as a material of the insulating film 614, it is preferable to form only the top end of the insulating film 614 to have a curvature radius (0.2 to 3 μm). As a material of the insulating film 614, either a negative photoresist which will not dissolve in etchant by light irradiation, or a positive photoresist which will dissolve in etchant by light irradiation can be used.

Over the first electrode 613, a layer 616 containing the light-emitting material shown in Embodiment Mode 1, and a second electrode 617 are formed in sequence. At least one of the first electrode 613 and the second electrode 617 has a light-transmitting property, through which light emitted from the layer 616 containing the light-emitting material can be extracted to outside.

Note that as the method for forming the first electrode 613, the layer 616 containing the light-emitting material, and the second electrode 617, various methods can be used. Specifically, the following can be used: a vacuum evaporation method such as resistance-heating evaporation or electron-beam evaporation (EB evaporation), a physical vapor deposition (PVD) method such as sputtering, a chemical vapor deposition (CVD) method such as metal organic CVD or low-pressure hydride transport CVD, an atomic layer epitaxy (ALE) method, or the like. Alternatively, an ink-jet deposition method, a spin coating method, or the like can also be used. In addition, it is also possible to form each electrode or each layer by a different film forming method.

By attaching the sealing substrate 604 to an element substrate 610 with the sealant 605, a structure where a light-emitting element 618 is formed in the space 607 which is surrounded by the element substrate 610, the sealing substrate 604, and the sealant 605 is obtained. Note that the space 607 is filled with a filling material which can be either an inert gas (e.g., nitrogen or argon) or the sealant 605.

As the sealant 605, an epoxy resin is preferably used. In addition, the sealant and the filling material are preferably the materials which transmit as little moisture and oxygen as possible. As a material used for the sealing substrate 604, a plastic substrate made of FRP (Fiberglass-Reinforced Plastics), PVF (PolyVinyl Fluoride), mylar, polyester, acrylic, or the like can be used as well as a glass substrate or a quartz substrate.

In this manner, a light-emitting device having the light-emitting element of the invention can be obtained.

The light-emitting device of the invention has a light-emitting element which includes a light-emitting material whose main crystal structure is hexagonal as shown in Embodiment Mode 1. Therefore, the light-emitting device can operate with a low driving voltage. Furthermore, high luminous efficiency can be realized. Thus, a high-luminance light-emitting device with reduced power consumption can be obtained.

In addition, since the light-emitting device of the invention does not require a driver circuit with high withstand voltage, the manufacturing cost of the light-emitting device can be reduced. Furthermore, reduction in weight of the light-emitting device and reduction in size of a driver circuit portion can be achieved.

### Embodiment Mode 6

This embodiment mode will describe an electronic device of the invention, which includes the light-emitting device shown in Embodiment Mode 5 as a component part. The electronic device of the invention includes a light-emitting element formed using the light-emitting material shown in Embodiment Mode 1. Therefore, since a high-luminance light-emitting element with a reduced driving voltage is used, a high-luminance electronic device with reduced power consumption can be provided.

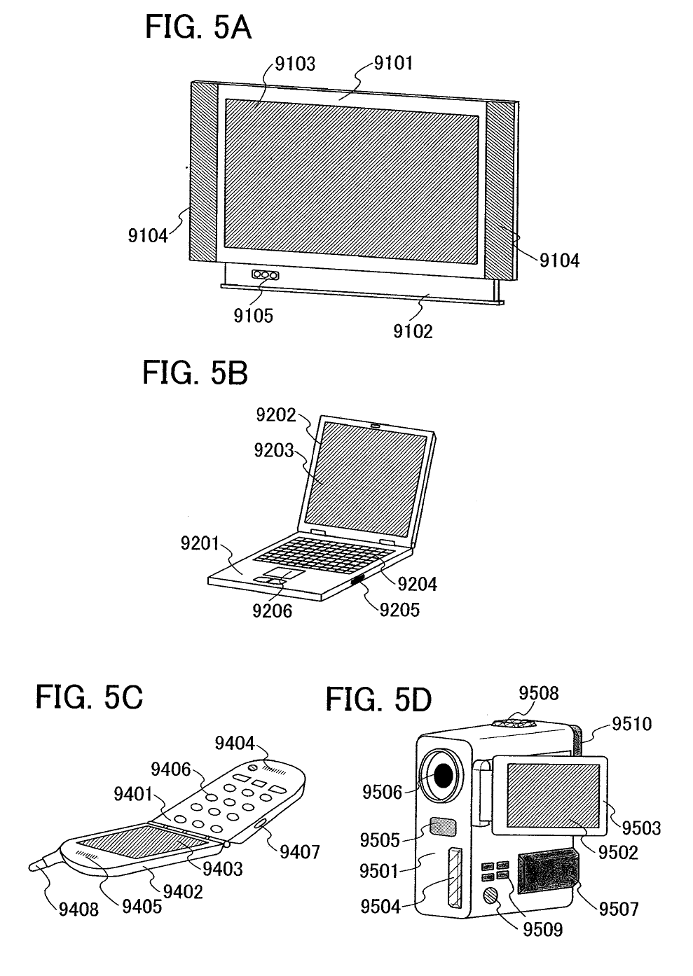

As examples of an electronic device formed using the light-emitting device of the invention, a camera (e.g., a video camera or a digital camera), a goggle display, a navigation system, an audio reproducing device (e.g., a car audio or an audio component set), a computer, a gate machine, a portable information terminal (e.g., a mobile computer, a mobile phone, a portable game machine, or an electronic book), an image reproducing device provided with a recording medium (specifically, a device for reproducing the content recorded in a storage medium such as a digital versatile disc (DVD) and having a display device for displaying the reproduced image), and the like can be given. Specific examples of such electronic devices are shown in FIGS. 5A to 5D.

FIG. 5A shows a television set in accordance with the invention, which includes a housing 9101, a support base 9102, a display portion 9103, speaker portions 9104, video input terminals 9105, and the like. In this television set, the display portion 9103 has a matrix arrangement of light-emitting elements which are formed using the light-emitting material shown in Embodiment Mode 1. The light-emitting elements have characteristics of high luminous efficiency and low driving voltage. Furthermore, short circuits which would be caused by external shocks and the like can be prevented. Since the display portion 9103 having such light-emitting elements has similar characteristics, this television set is free from deterioration of image quality and has low power consumption. With such characteristics, the number or scale of power supply circuits in the television set can be drastically reduced, and therefore, the size and weight of the housing 9101 and the support base 9102 can be reduced. Since the television set in accordance with the invention can achieve low power consumption, high image quality, and reduction in size and weight, a product suitable for living environments can be provided.

FIG. 5B shows a computer in accordance with the invention, which includes a main body 9201, a housing 9202, a display portion 9203, a keyboard 9204, an external connection port 9205, a pointing device 9206, and the like. In this computer, the display portion 9203 has a matrix arrangement of light-emitting elements which are formed using the light-emitting material shown in Embodiment Mode 1. The light-emitting elements have characteristics of high luminous efficiency and low driving voltage. Furthermore, short circuits which would be caused by external shocks and the like can be prevented. Since the display portion 9203 having such light-emitting elements has similar characteristics, this computer is free from deterioration of image quality and has low power consumption. With such characteristics, the number or scale of power supply circuits in the computer can be drastically reduced, and therefore, the size and weight of the main body 9201 and the housing 9202 can be reduced. Since the computer in accordance with the invention can achieve low power consumption, high image quality, and reduction in size and weight, a product suitable for living environments can be provided. Furthermore, the computer can be carried about, and thus a computer having a display portion with high impact resistance while it is carried can be provided.

FIG. 5C shows a mobile phone in accordance with the invention, which includes a main body 9401, a housing 9402, a display portion 9403, an audio input portion 9404, an audio output portion 9405, operation keys 9406, an external connection port 9407, an antenna 9408, and the like. In this mobile phone, the display portion 9403 has a matrix arrangement of light-emitting elements which are formed using the light-emitting material shown in Embodiment Mode 1. The light-emitting elements have characteristics of high luminous efficiency and low driving voltage. Furthermore, short circuits which would be caused by external shocks and the like can be prevented. Since the display portion 9403 having such light-emitting elements has similar characteristics, this mobile phone is free from deterioration of image quality and has low power consumption. With such characteristics, the number or scale of power supply circuits in the mobile phone can be drastically reduced, and therefore, the size and weight of the main body 9401 and the housing 9402 can be reduced. Since the mobile phone in accordance with the invention can achieve low power consumption, high image quality, and reduction in size and weight, a product suitable for portable use can be provided. In addition, a product having a display portion with high impact resistance while it is carried can be provided.

FIG. 5D shows a camera in accordance with the invention, which includes a main body 9501, a display portion 9502, a housing 9503, an external connection port 9504, a remote controller receiving portion 9505, an image receiving portion 9506, a battery 9507, an audio input portion 9508, operating keys 9509, an eyepiece portion 9510, and the like. In this camera, the display portion 9502 has a matrix arrangement of light-emitting elements which are formed using the light-emitting material shown in Embodiment Mode 1. The light-emitting elements have characteristics of high luminous efficiency and low driving voltage. Furthermore, short circuits which would be caused by external shocks and the like can be prevented. Since the display portion 9502 having such light-emitting elements has similar characteristics, this camera is free from deterioration of image quality and has low power consumption. With such characteristics, the number or scale of power supply circuits in the camera can be drastically reduced, and therefore, the size and weight of the main body 9501 can be reduced. Since the camera in accordance with the invention can achieve low power consumption, high image quality, and reduction in size and weight, a product suitable for portable use can be provided. In addition, a product having a display portion with high impact resistance while it is carried can be provided.

As described above, the applicable range of the light-emitting device of the invention is so wide that the light-emitting device can be applied to electronic devices in various fields. By using the light-emitting device of the invention, an electronic device having a display portion with low power consumption, high luminance, and high reliability can be provided.

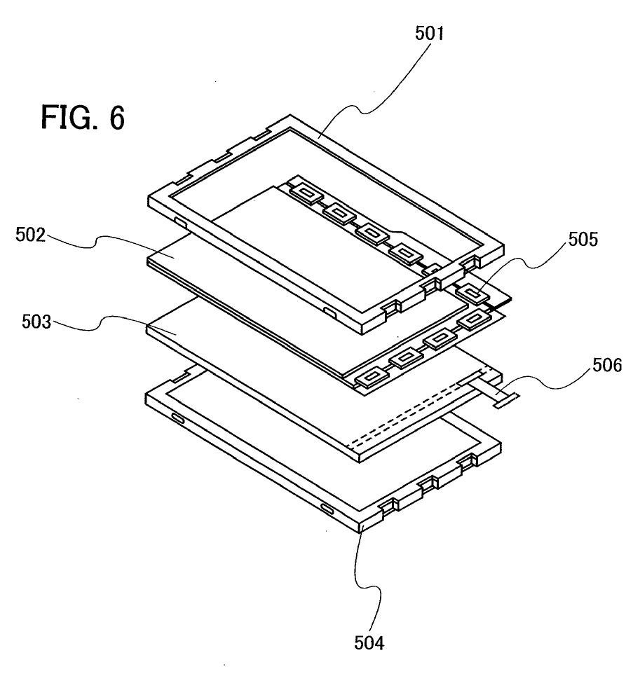

The light-emitting device of the invention has a light-emitting element with high luminous efficiency, and it can also be used as a lighting apparatus. An example of using the light-emitting element of the invention as a lighting apparatus is described with reference to FIG. 6.

FIG. 6 shows an example of a liquid crystal display device which uses the light-emitting device of the invention as a backlight. The liquid crystal display device shown in FIG. 6 includes a housing 501, a liquid crystal layer 502, a backlight 503, and a housing 504, and the liquid crystal layer 502 is connected to a driver IC 505. In addition, the light-emitting device of the invention is used for the backlight 503, which receives current from a terminal 506.

By using the light-emitting device of the invention as a backlight of the liquid crystal display device, a backlight with reduced power consumption and high luminance can be obtained. In addition, since the light-emitting device of the invention is a surface-emission lighting apparatus, the size of which can be increased, the size of the backlight can also be increased, thereby the size of the liquid crystal display device can also be increased. Furthermore, since the light-emitting device is thin and has low power consumption, reduction in thickness and power consumption of the display device can be achieved.

### Embodiment 1

This embodiment will describe a difference in crystal structure between the case of using a mixed material of ZnS and Mn as a light-emitting material, the case of using a mixed material of ZnS and MnS as a light-emitting material, and the case of using a mixed material of ZnS, MnS, and Si as a light-emitting material. Note that in this embodiment, the mixed material of ZnS and Mn is represented by ZnS:Mn, the mixed material of ZnS and MnS is represented by ZnS:MnS, and the mixed material of ZnS, MnS, and Si is represented by ZnS:MnS:Si.

First, ZnS which is a host material of the light-emitting material and Mn which is a luminescence center were ground and mixed in an agate mortar in an nitrogen atmosphere so that Mn was dispersed in ZnS. In addition, ZnS which is a host material of the light-emitting material and MnS which is a luminescence center were ground and mixed in an agate mortar in an nitrogen atmosphere so that MnS was dispersed in ZnS. Furthermore, Si was added into ZnS which is a host material of the light-emitting material and MnS which is a luminescence center, and they were ground and mixed in an agate mortar in an nitrogen atmosphere, so that MnS was dispersed in ZnS. After that, each material was put into a crucible and baked in a nitrogen-substituted electric furnace, which had been pre-heated to 150° C. for one hour, at 1000° C. for four hours. Upon completion of the baking, the material was standed to cool for a while and then taken out of the furnace, so that ZnS:Mn, ZnS:MnS, and ZnS:MnS:Si were formed.

In the case of the light-emitting material including ZnS:Mn, the mixing ratio was set as: 5 g of ZnS and 84.5 mg of Mn. With this mixing ratio, suppose the mol percentage of ZnS is 100 mol %, the mol percentage of Mn is about 3 mol %. In the case of the light-emitting material including ZnS:MnS, the mixing ratio was set as: 5 g of ZnS and 134 mg of MnS. With this mixing ratio, suppose the mol percentage of ZnS is 100 mol %, the mol percentage of MnS is about 3 mol %. In the case of the light-emitting material including ZnS:MnS:Si, the mixing ratio was set as: 5 g of ZnS, 134 mg of MnS, and 14.5 mg of Si. With this mixing ratio, suppose the mol percentage of ZnS is 100 mol %, the mol percentage of MnS is about 3 mol % and the mol percentage of Si is about 1 mol %.

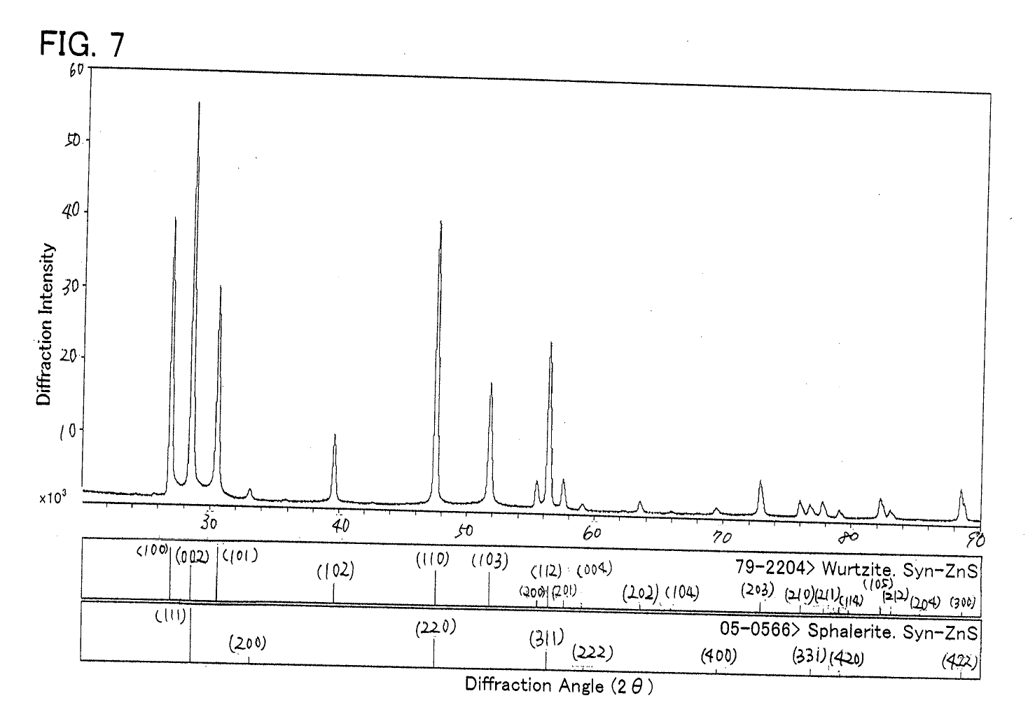

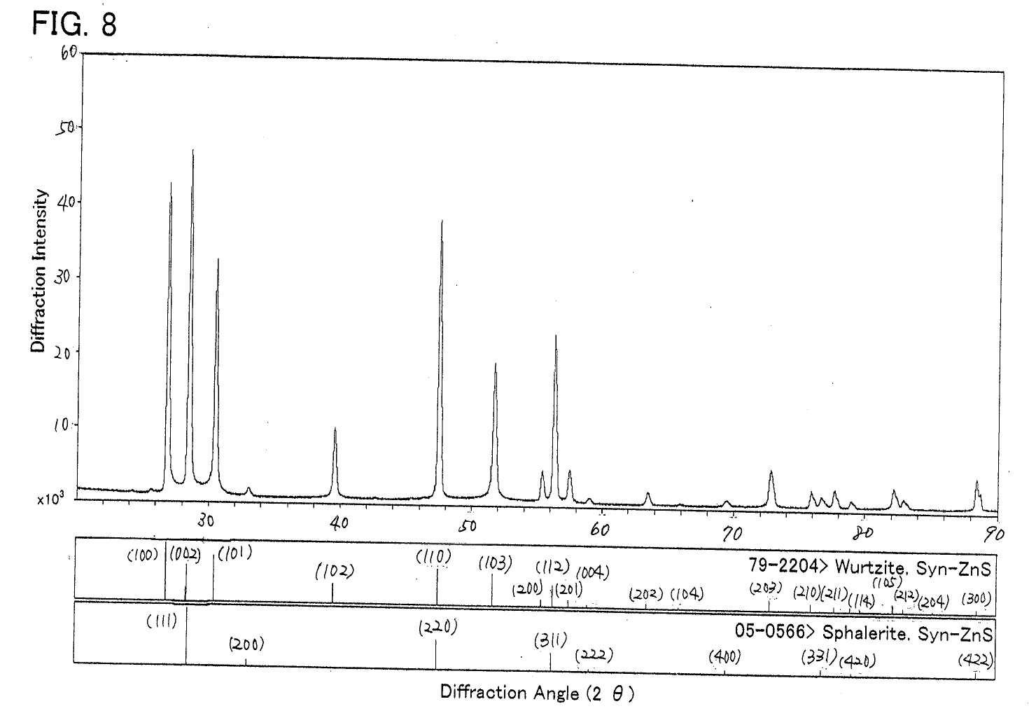

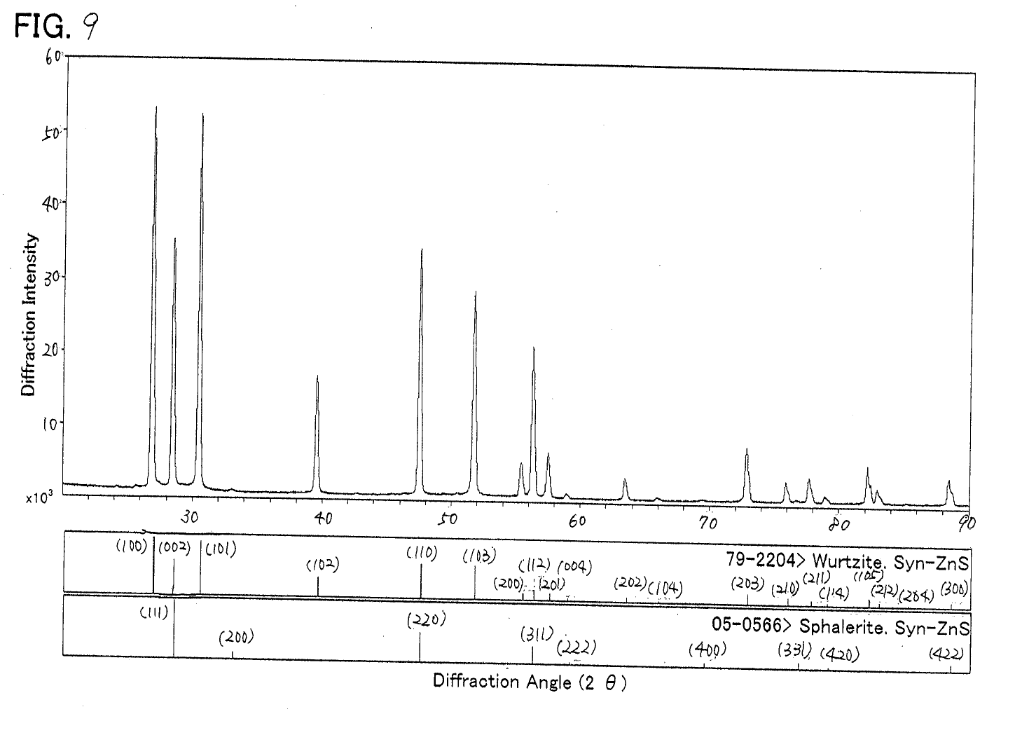

The light-emitting materials were measured by an X-ray diffraction (XRD) method. FIG. 7 shows the measurement result of ZnS:Mn by XRD analysis, FIG. 8 shows the measurement result of ZnS:MnS by XRD analysis, and FIG. 9 shows the measurement result of ZnS:MnS:Si by XRD analysis. In FIGS. 7 to 9, the vertical axis shows the diffraction intensity (arbitrary unit), and the horizontal axis shows the diffraction angles of x rays. In addition, Wurtzite.syn-ZnS shows peak patterns of hexagonal crystals of ZnS, while Sphalerite.syn-ZnS shows peak patterns of cubic crystals of ZnS.

As can be seen in FIGS. 7 to 9, the peak intensity, from lowest to highest, of hexagonal crystals of ZnS:Mn, ZnS:MnS, and ZnS:MnS:Si satisfies ZnS:Mn<ZnS:MnS<ZnS:MnS:Si, while the peak intensity, from lowest to highest, of cubic crystals of ZnS:Mn, ZnS:MnS, and ZnS:MnS:Si satisfies ZnS:MnS:Si<ZnS:MnS<ZnS:Mn. Accordingly, it can be said that the crystal structure of ZnS:MnS:Si has a higher percentage of hexagonal crystals than the crystal structure of ZnS:Mn. In addition, when the intensity of phostoluminescence (PL) of each light-emitting material was measured after baking, the PL intensity satisfied the relationship of ZnS:Mn<ZnS:MnS<ZnS:MnS:Si. Thus, high PL intensity was obtained from ZnS:MnS:Si. From the results, it can be said that a light-emitting material with a hexagonal crystal structure can exhibit higher luminance.

This application is based on Japanese Patent Application serial no. 2006-058757 filed in Japan Patent Office on Mar. 3, 2006, the entire contents of which are hereby incorporated by reference.

### REFERENCE NUMERALS

60: first electrode, 61: light-emitting material, 62: light-emitting layer, 63: second electrode, 64: dielectric layer, 64a: dielectric layer, 64b: dielectric layer, 100: substrate, 101: first electrode, 102: first dielectric layer, 103: light-emitting layer, 104: second dielectric layer, 105: second electrode, 501: housing, 502: liquid crystal layer, 503: backlight, 504: housing, 505: driver IC, 601: source driver circuit, 602: pixel portion, 603: gate driver circuit, 604: sealing substrate, 605: sealant, 607: space, 608: wire, 609: FPC (Flexible Printed Circuit), 610: element substrate, 611: switching TFT, 612: current-controlling TFT, 613: first electrode, 614: insulating film, 616: layer containing a light-emitting substance, 617: second electrode, 618: light-emitting element, 623: n-channel TFT, 624: p-channel TFr, 951: substrate, 952: electrode, 953: insulating layer, 954: partition layer, 955: layer, 956: electrode, 1501: first electrode, 1502: first insulating film, 1503: light-emitting layer, 1504: second insulating film, 1505: second electrode, 1506: first power supply, 1507: second power supply, 9101: housing, 9102: support base, 9103: display portion, 9104: speaker portion, 9105: video input terminal, 9201: main body, 9202: housing, 9203: display portion, 9204: keyboard, 9205: external connection port, 9206: pointing device, 9401: main body, 9402: housing, 9403: display portion, 9404: audio input portion, 9405: audio output portion, 9406: operation key, 9407: external connection port, 9408: antenna, 9501: main body, 9502: display portion, 9503: housing, 9504: external connection port, 9505: remote controller receiving portion, 9506: image receiving portion, 9507: battery, 9508: audio input portion, 9509: operation key, and 9510: eyepiece portion

1. A light-emitting material comprising:
a host material;
an impurity element; and
a Group 14 element,
wherein a main crystal structure of the light-emitting material is hexagonal;
wherein the host material comprises at least one of a compound of a Group 2 element and a Group 16 element and a compound of a Group 12 element and a Group 16 element; and
wherein the impurity element includes at least one selected from the group consisting of manganese (Mn), samarium (Sm), terbium (Tb), erbium (Er), thulium (Tm), europium (Eu), cerium (Ce), and praseodymium (Pr).

2. A light-emitting material comprising:
a host material; and
an impurity element,
wherein a main crystal structure of the light-emitting material is hexagonal;
wherein the host material comprises at least one of a compound of a Group 2 element and a Group 16 element and a compound of a Group 12 element and a Group 16 element, and
wherein the impurity element includes at least one selected from the group consisting of manganese (Mn), samarium (Sm), terbium (Tb), erbium (Er), thulium (Tm), europium (Eu), cerium (Ce), and praseodymium (Pr).

3. The light-emitting material according to claim 1, wherein the Group 14 element comprises at least one selected from the group consisting of carbon (C), silicon (Si), germanium (Ge), tin (Sn), and lead (Pb).

4. The light-emitting material according to claim 1 or 2, wherein the compound of the Group 2 element and the Group 16 element includes at least one selected from the group consisting of magnesium oxide (MgO), calcium oxide (CaO), strontium oxide (SrO), barium oxide (BaO), magnesium sulfide (MgS), calcium sulfide (CaS), strontium sulfide (SrS), barium sulfide (BaS), magnesium selenide (MgSe), calcium selenide (CaSe), strontium selenide (SrSe), barium selenide (BaSe), magnesium telluride (MgTe), calcium telluride (CaTe), strontium telluride (SrTe), and barium telluride (BaTe).

5. The light-emitting material according to claim 1 or 2, wherein the compound of the Group 12 element and the Group 16 element includes at least one selected from the group consisting of zinc oxide (ZnO), cadmium oxide (CdO), mercury oxide (HgO), zinc sulfide (ZnS), cadmium sulfide (CdS), mercury sulfide (HgS), zinc selenide (ZnSe), cadmium selenide (CdSe), mercury selenide (HgSe), zinc telluride (ZnTe), cadmium telluride (CdTe), and mercury telluride (HgTe).

6. A light-emitting element comprising:
a first electrode;
a second electrode; and
a light-emitting layer interposed between the first electrode and the second electrode, the light-emitting layer including a light-emitting material comprising;
a host material; and
an impurity element,
wherein a main crystal structure of the light-emitting material is hexagonal;
wherein the host material comprises at least one of a compound of a Group 2 element and a Group 16 element and a compound of a Group 12 element and a Group 16 element, and
wherein the impurity element includes at least one selected from the group consisting of manganese (Mn), samarium (Sm), terbium (Tb), erbium (Er), thulium (Tm), europium (Eu), cerium (Ce), and praseodymium (Pr).

7. A light-emitting element comprising:
a first electrode;
a second electrode; and
a light-emitting layer interposed between the first electrode and the second electrode, the light-emitting layer including a light-emitting material comprising:
a host material;
an impurity element; and
a Group 14 element,
wherein a main crystal structure of the light-emitting material is hexagonal;
wherein the host material comprises a compound of a Group 2 element and a Group 16 element and a compound of a Group 12 element and a Group 16 element, and
wherein the impurity element includes at least one selected from the group of manganese (Mn), samarium (Sm), terbium (Tb), erbium (Er), thulium (Tm), europium (Eu), cerium (Ce), and praseodymium (Pr).

8. The light-emitting element according to claim 7, wherein the Group 14 element comprises at least one selected from the group consisting of carbon (C), silicon (Si), germanium (Ge), tin (Sn), and lead (Pb).

9. The light-emitting element according to claim 6 or 7, wherein the compound of the Group 2 element and the Group 16 element includes at least one selected from the group consisting of magnesium oxide (MgO), calcium oxide (CaO), strontium oxide (SrO), barium oxide (BaO), magnesium sulfide (MgS), calcium sulfide (CaS), strontium sulfide (SrS), barium sulfide (BaS), magnesium selenide (MgSe), calcium selenide (CaSe), strontium selenide (SrSe), barium selenide (BaSe), magnesium telluride (MgTe), calcium telluride (CaTe), strontium telluride (SrTe), and barium telluride (BaTe).

10. The light-emitting element according to claim 6 or 7, wherein the compound of the Group 12 element and the Group 16 element includes at least one selected from the group consisting of zinc oxide (ZnO), cadmium oxide (CdO), mercury oxide (HgO), zinc sulfide (ZnS), cadmium sulfide (CdS), mercury sulfide (HgS), zinc selenide (ZnSe), cadmium selenide (CdSe), mercury selenide (HgSe), zinc telluride (ZnTe), cadmium telluride (CdTe), and mercury telluride (HgTe).

11. A light-emitting device comprising the light-emitting element according to claim 6 or 7.

12. An electronic device comprising the light-emitting element according to claim 6 or 7.

13. A manufacturing method of a light-emitting material, comprising the step of:
forming a main crystal structure into a hexagonal crystal structure by baking a host material and an impurity element,
wherein the host material comprises at least one of a compound of a Group 2 element and a Group 16 element and a compound of a Group 12 element and a Group 16 element, and
wherein the impurity element includes at least one selected from the group consisting of manganese (Mn), samarium (Sm), terbium (Tb), erbium (Er), thulium (Tm), europium (Eu), cerium (Ce), and praseodymium (Pr).

14. A manufacturing method of a light-emitting material, comprising the step of:
forming a main crystal structure into a hexagonal crystal structure by baking a host material, an impurity element, and a Group 14 element,
wherein the host material comprises at least one of a compound of a Group 2 element and a Group 16 element and a compound of a Group 12 element and a Group 16 element, and
wherein the impurity element includes at least one selected from the group consisting of manganese (Mn), samarium (Sm), terbium (Tb), erbium (Er), thulium (Tm), europium (Eu), cerium (Ce), and praseodymium.

15. The manufacturing method of a light-emitting material according to claim 14, wherein the Group 14 element comprises at least one selected from the group consisting of carbon (C), silicon (Si), germanium (Ge), tin (Sn), or lead (Pb).

16. The manufacturing method of a light-emitting material according to claim 13 or 14, wherein the compound of the Group 2 element and the Group 16 element includes at least one selected from the group consisting of magnesium oxide (MgO), calcium oxide (CaO), strontium oxide (SrO), barium oxide (BaO), magnesium sulfide (MgS), calcium sulfide (CaS), strontium sulfide (SrS), barium sulfide (BaS), magnesium selenide (MgSe), calcium selenide (CaSe), strontium selenide (SrSe), barium selenide (BaSe), magnesium telluride (MgTe), calcium telluride (CaTe), strontium telluride (SrTe), and barium telluride (BaTe).

17. The manufacturing method of a light-emitting material according to claim 13 or 14, wherein the compound of the Group 12 element and the Group 16 element includes at least one selected from the group consisting of zinc oxide (ZnO), cadmium oxide (CdO), mercury oxide (HgO), zinc sulfide (ZnS), cadmium sulfide (CdS), mercury sulfide (HgS), zinc selenide (ZnSe), cadmium selenide (CdSe), mercury selenide (HgSe), zinc telluride (ZnTe), cadmium telluride (CdTe), and mercury telluride (HgTe).
